(19) United States
(12) Patent Application Publication
(10) Pub. No.: US 2020/0227577 A1
(43) Pub. Date: Jul. 16, 2020

(54) SOLAR CELL BACKSHEET

(71) Applicant: ZHONGTIAN PHOTOVOLTAIC MATERIALS Co.,LTD., Nantong (CN)

(72) Inventors: XIANG-AN LIU, Nantong (CN); QIANG WANG, Nantong (CN); TONG-XIN WANG, Nantong (CN); KUN CHEN, Nantong (CN); MING-LONG JI, Nantong (CN)

(21) Appl. No.: 16/832,053

(22) Filed: Mar. 27, 2020

Related U.S. Application Data
(63) Continuation-in-part of application No. PCT/CN2017/104026, filed on Sep. 28, 2017.

(30) Foreign Application Priority Data
Sep. 27, 2017 (CN) 201710887257.7

(51) Int. Cl. H01L 31/049; H01L 31/048; C09J 175/04

(52) U.S. Cl. CPC H01L 31/049; C09J 175/04; H01L 31/0481

(57) ABSTRACT

A solar cell backsheet includes a weathering layer, a first adhesive layer, a polyethylene terephthalate (PET) layer, a second adhesive layer, and a functional layer. The weathering layer, the first adhesive layer, the PET layer, the second adhesive layer, and the functional layer are arranged in said sequence. The functional layer includes a milky layer and a transparent layer, the milky layer and the transparent layer being integrally formed.

### FIELD

The subject matter herein generally relates to solar cells, and more particularly to a solar cell backsheet.

### BACKGROUND

A crystalline silicon solar cell module generally includes eight elements: glass, a packaging film, a cell sheet, solder tape, silicone, an aluminum frame, a junction box, and photovoltaic backsheet. The photovoltaic backsheet is an extremely important packaging material in photovoltaic modules. The photovoltaic backsheet supports the cell sheet while directly contacts a large area of the external environment, it provides important functions of ensuring stable photovoltaic power generation for 25 years, and insulation and barrier, weatherability, reliability, and longitivity of the solar cell.

Conventional photovoltaic backsheets generally have a layer of adhesive film added between the backsheet and the cell sheet, and be covered with this adhesive film.

Using an integrated adhesive film-backsheet structure may introduce defects in use.

In Chinese Patent No. 201320281107.9, the integrated adhesive film-backsheet structure of the solar photovoltaic module comprises an EVA substitute layer, a structural reinforcement layer, and a weathering layer in said sequence from the outer layer facing the cell sheet. The EVA substitute layer is a single-layer structure. After lamination, there are many defects, which are mainly manifested as: (1) after lamination, the EVA substitute layer is squeezed by the structural reinforcement layer and glass, and a phenomenon of edge overflow and delamination may occur; (2) the EVA substitute layer is a micro-foamed polyolefin structure, which is relatively soft, and during the lamination process, the cell sheet and the solder tape completely penetrate the EVA substitute layer and directly contact the structural reinforcement layer, which may cause the cell sheet to crack and fragment; (3) more serious defects are due to the conductor completely penetrating the EVA substitute layer, the EVA substitute layer completely loses its insulating function, so that only the weathering layer and the structural reinforcement layer are relied on for insulation, and the overall insulation thickness is reduced.

### SUMMARY

The present disclosure discloses a solar cell backsheet, the photovoltaic backsheet from outside to inside including a weathering layer, an adhesive layer, a PET layer, an adhesive layer, and a functional layer, the functional layer including an integrally formed milky layer and a transparent layer, wherein the milky layer includes at least one layer and has a thickness of 20-200 μm, and includes at least 3 parts of a modified inorganic filler, at least 70 parts of a modified resin, at least 0.3 parts of a UV absorber, and at least 0.3 parts of an antioxidant. The transparent layer is bonded to the cell sheet, includes at least one layer and has a thickness of 200-800 μm, and includes at least 90 parts of a modified resin, at least 0.3 parts of a UV absorber, and at least 0.3 parts of an antioxidant.

In one implementation of the present disclosure, the milky layer includes a plurality of layers. The content of the modified resin in the layer of the milky layer bonded to the transparent layer is not higher than the content of the modified resin in the milky layer bonded to the adhesive layer, and the thickness of the layer of the milky layer combined with the transparent layer is not higher than the thickness of the layer of the milky layer bonded to the adhesive layer.

In one implementation of the present disclosure, the transparent layer includes a plurality of layers. The content of the modified resin in the layer of the transparent layer bonded to the cell sheet is not lower than the content of the modified resin in the layer of the transparent layer bonded to the milky layer, and the thickness of the layer of the transparent layer bonded to the cell sheet is not higher than the thickness of the layer of the transparent layer bonded to the milky layer.

In one implementation of the present disclosure, the weathering layer has a thickness of 5-200 μm and is a fluorine-containing or non-fluorine-containing layer.

In one implementation of the present disclosure, the adhesive layer is an acrylic adhesive, a urethane adhesive, an epoxy resin adhesive, or a resin adhesive having a thickness of 5-30 μm.

In one implementation of the present disclosure, the modified resin is one or a combination of polyethylene, polypropylene, an ethylene copolymer, a polyolefin elastomer, and a polyolefin plastomer.

In one implementation of the present disclosure, the modified inorganic filler is one or a combination of titanium dioxide, montmorillonite, kaolin, mica, talc, wollastonite, and brucite. The modification method used is a wrapping method, a chemical vapor precipitation method, a local chemical reaction method, a low temperature plasma method, a high energy radiation method, an electron beam ray method, or an ultraviolet method.

In one implementation of the present disclosure, both major sides of the functional layer are embossed by an embossing roll to form a microstructure.

In one implementation of the present disclosure, the transparent layer and the milky layer are single or double layers, and the combination of the transparent layer and the milky layer includes a single-layer milky layer and a single-layer transparent layer, a double-layer milky layer and a single-layer transparent layer, a single-layer milky layer and a double-layer transparent layer, and a double-layer milky layer and a double-layer transparent layer.

### BRIEF DESCRIPTION OF THE DRAWINGS

FIG. 1 is a schematic structural diagram according to the present disclosure.

FIG. 2 is a schematic diagram of a first embodiment according to the present disclosure.

FIG. 3 is a schematic diagram of a second embodiment according to the present disclosure.

FIG. 4 is a schematic diagram of a third embodiment according to the present disclosure.

FIG. 5 is a schematic diagram of a fourth embodiment according to the present disclosure.

### DETAILED DESCRIPTION

The present disclosure will be clearly and completely described below with reference to the accompanying drawings of the present disclosure.

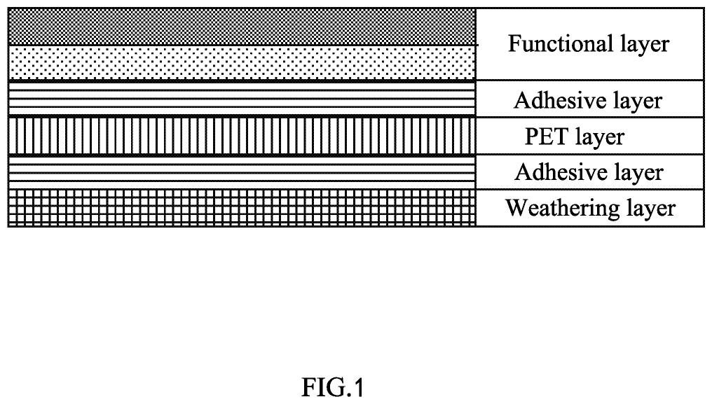

As shown in FIG. 1, a solar cell backsheet disclosed by the present disclosure, the photovoltaic backsheet from outside to inside includes a weathering layer, an adhesive layer, a polyethylene terephthalate (PET) layer, an adhesive layer, and a functional layer, wherein:

A thickness of the weathering layer is 5-200 μm, which is a fluorine-containing or non-fluorine-containing layer; The adhesive layer is an acrylic adhesive, a polyurethane adhesive, an epoxy resin adhesive, or a resin adhesive, and the thickness is 5˜30 μm;

A thickness of the PET layer is 80-400 μm.

The functional layer includes an integrally formed milky layer and a transparent layer, wherein:

The milky layer can include one layer or a plurality of layers (not more than three layers, preferably two layers), with a total thickness of 20-200 composed of a modified inorganic filler, a modified resin, an ultraviolet absorber, and an antioxidant. When the milky layer includes one layer, a composition ratio is at least 3 parts of modified inorganic filler, at least 70 parts of modified resin, at least 0.3 parts of ultraviolet absorbent, and at least 0.3 parts of antioxidant. In the case of a plurality of layers, each layer can be fine-tuned based on the thickness and the composition ratio of the single-layer structure, but it is necessary to ensure that the ratio of the modified resin in the layer of the milky layer combined with the transparent layer is not higher than the ratio of the modified resin in the layer of the milky layer combined with the adhesive layer, and at the same time, the thickness of the layer of the milky layer combined with the transparent layer must not be higher than the thickness of the layer of the milky layer combined with the adhesive layer.

The transparent layer is bonded to the cell sheet, and may also include one layer or a plurality of layers (not more than three layers, preferably two layers), with a total thickness of 200-800 μm, and composed of a modified resin, an ultraviolet absorber, and an antioxidant. When the transparent layer includes one layer, the composition ratio is at least 90 parts of modified resin, at least 0.3 parts of UV absorber, and at least 0.3 parts of antioxidant. In the case of a plurality of layers, each layer can be fine-tuned based on the thickness and the composition ratio of the single-layer structure, but it is necessary to insure that the ratio of the modified resin in the layer of the transparent layer combined with the cell sheet is not lower than the ratio of the modified resin in the layer of the transparent layer combined with the milky layer, and at the same time, the thickness of the layer of the transparent layer combined with the cell sheet must not be higher than the thickness of the layer of the transparent layer combined with the milky layer.

The following describes the contents of the present disclosure in detail with specific embodiments.

### First Embodiment

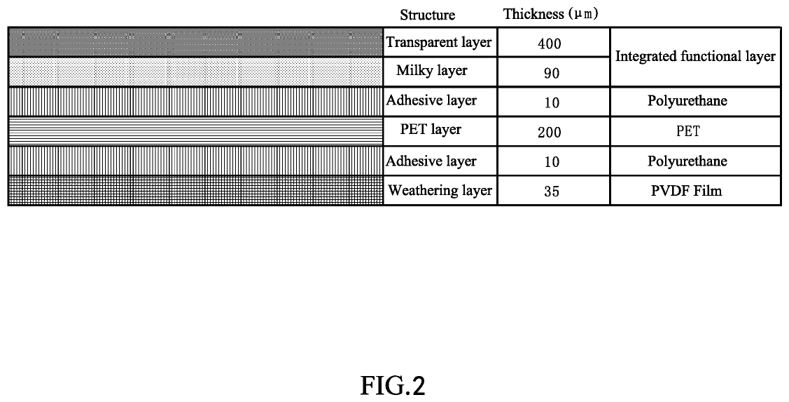

As shown in FIG. 2, a solar cell backsheet disclosed by the present disclosure includes a weathering layer, an adhesive layer, a PET layer, an adhesive layer, and a functional layer in sequence from outside to inside. The weathering layer is a polyvinylidene fluoride (PVDF) film with a thickness of 35 μm. The adhesive layer is a polyurethane adhesive with a thickness of 10 μm. A thickness of the PET layer is 200 μm. The functional layer includes a single-layer milky layer and a single-layer transparent layer. The milky layer is adhered to the PET layer and has a thickness of 90 μm, and consists of 25 parts of polyethylene, 45 parts of polyolefin elastomer, 19 parts of polyolefin plastomer, 10 parts of titanium dioxide, 0.4 parts of antioxidant, and 0.6 parts of UV absorber. The transparent layer is bonded to the cell sheet and has a thickness of 400 μm. The transparent layer is composed of 60 parts of polyolefin elastomer, 39 parts of ethylene-vinyl acetate copolymer, 0.4 parts of antioxidant, and 0.4 parts of ultraviolet absorber.

The backsheet of this embodiment is laminated with the cell sheet, an EVA film, and glass, and then tested. A peel strength between the milky layer and the transparent layer is greater than 40 N/cm, a peel strength between the functional layer and the PET layer is greater than 7 N/cm, adhesion to the cell sheet is greater than 30 N/cm, and adhesion to the EVA of the upper layer of the cell sheet is greater than 100 N/cm. The effective insulation thickness of the DTI test backsheet is greater than 340 μm, and the module is subjected to EL testing. The cell sheet before and after lamination does not show cracking or fragmentation.

### Second Embodiment

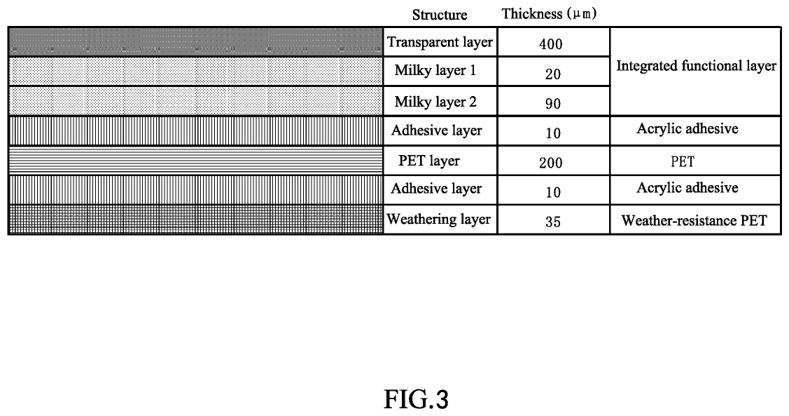

As shown in FIG. 3, a solar cell backsheet disclosed by the present disclosure includes a weathering layer, an adhesive layer, a PET layer, an adhesive layer, and a functional layer in sequence from outside to inside. The weathering layer is a weather-resistant PET having a thickness of 35 μm. The adhesive layer is acrylic adhesive having a thickness of 10 μm. A thickness of the PET layer is 200 μm. The functional layer includes a double-layer milky layer and a single-layer transparent layer. The bottom milky layer has a thickness of 90 μm and is composed of 25 parts of polyethylene, 45 parts of polyolefin elastomer, 19 parts of polyolefin plastomer, 10 parts of titanium dioxide, 0.4 parts of antioxidant, and 0.6 parts of ultraviolet absorber. A thickness of the upper milky layer is 20 μm and is composed of 29 parts of polyethylene, 55 parts of polyolefin elastomer, 5 parts of polyolefin plastomer, 10 parts of titanium dioxide, 0.4 parts of antioxidant, and 0.6 parts of ultraviolet absorber. The transparent layer is bonded to the cell sheet and has a thickness of 400 μm and is composed of 60 parts of olefin elastomer, 39 parts of ethylene-vinyl acetate copolymer, 0.4 parts of antioxidant, and 0.6 parts of ultraviolet absorber.

The backsheet of this embodiment is laminated with the cell sheet, the EVA film, and the glass and then tested. The peel strength between the milky layer and the transparent layer is greater than 45 N/cm. The peel strength between the functional layer and the PET layer is greater than 7 N/cm, adhesion to the cell sheet is greater than 30 N/cm, and adhesion to the EVA of the upper layer of the cell sheet is greater than 100 N/cm. The effective insulation thickness of the DTI test backsheet is greater than 340 μm, and the module is subjected to EL testing. The cell sheet before and after lamination does not show cracking or fragmentation.

### Third Embodiment

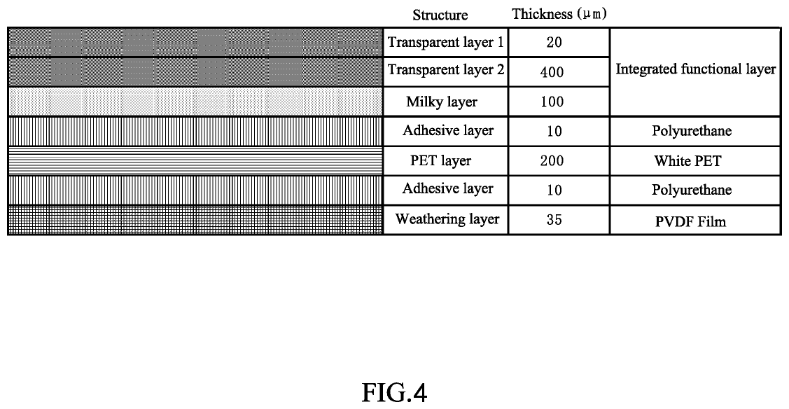

As shown in FIG. 4, a solar cell backsheet disclosed by the present disclosure includes a weathering layer, an adhesive layer, a PET layer, an adhesive layer, and a functional layer in sequence from outside to inside. The weathering layer is a PVDF film with a thickness of 35 The adhesive layer is a polyurethane adhesive with a thickness of 10 μm. A thickness of the PET layer is 200 The functional layer includes a single-layer milky layer and a double-layer transparent layer. The milky layer has a thickness of 100 μm and is composed of 25 parts of polyethylene, 45 parts of polyolefin elastomer, 19 parts of polyolefin plastomer, 10 parts of titanium dioxide, 0.4 parts of antioxidant, and 0.6 parts of ultraviolet absorber. The lower transparent layer has a thickness of 400 μm and is composed of 60 parts of polyolefin elastomer, 39 parts of ethylene-vinyl acetate copolymer, 0.4 parts of antioxidant, and 0.6 parts of ultraviolet absorber. The upper transparent layer has a thickness of 20 μm and is composed of 40 parts of polyolefin elastomer, 59 parts of ethylene-vinyl acetate copolymer, 0.4 parts of antioxidant, and 0.6 parts of UV absorber.

The backsheet of this embodiment is laminated with the cell sheet, EVA film, and glass, and then tested. The peel strength between the milky layer and the transparent layer is greater than 45 N/cm. The peel strength between the functional layer and the PET layer is greater than 7 N/cm. Adhesion to the cell sheet is greater than 50 N/cm. Adhesion to the EVA of the upper layer of the cell sheet is greater than 120 N/cm. The effective insulation thickness of the DTI test backsheet is greater than 340 μm, and the module is subjected to EL testing. The cell sheet before and after lamination does not show cracking or fragmentation.

### Fourth Embodiment

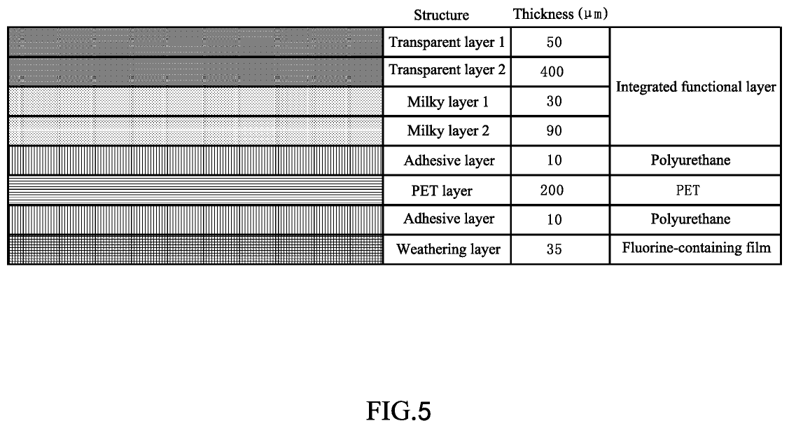

As shown in FIG. 5, a solar cell backsheet disclosed by the present disclosure includes a weathering layer, an adhesive layer, a PET layer, an adhesive layer, and a functional layer in sequence from outside to inside. The weathering layer is a fluorine-containing film with a thickness of 35 μm. The adhesive layer is a polyurethane adhesive with a thickness of 10 μm. The PET layer has a thickness of 200 μm. The functional layer includes a double-layer milky layer and a double-layer transparent layer. The lower milky layer has a thickness of 90 μm and is composed of 25 parts of polyethylene, 45 parts of polyolefin elastomer, 19 parts of polyolefin plastomer, 10 parts of titanium dioxide, 0.4 parts of antioxidant, and 0.6 parts of ultraviolet absorber. The upper milky layer has a thickness of 30 μm and is composed of 29 parts of polyethylene, 55 parts of polyolefin elastomer, 5 parts of polyolefin plastomer, 10 parts of titanium dioxide, 0.4 parts of antioxidant, and 0.6 parts of UV absorber. The lower transparent layer has a thickness of 400 μm and is composed of 60 parts of polyolefin elastomer, 39 parts of ethylene-vinyl acetate copolymer, 0.4 parts of antioxidant, and 0.6 parts of ultraviolet absorber. The upper transparent layer has a thickness of 50 μm and is composed of 40 parts of polyolefin elastomer, 59 parts of ethylene-vinyl acetate copolymer, 0.4 parts of antioxidant, and 0.6 parts of ultraviolet absorber.

The backsheet of this embodiment is laminated with the cell sheet, EVA film, and glass, and then tested. The peel strength between the milky layer and the transparent layer is greater than 50 N/cm. The peel strength between the functional layer and the PET layer is greater than 7 N/cm. Adhesion to the cell sheet is greater than 50 N/cm. Adhesion to the EVA of the upper layer of the cell sheet is greater than 120 N/cm. The effective insulation thickness of the DTI test backsheet is greater than 340 μm, and the module is subjected to EL testing. The cell sheet before and after lamination does not show cracking or fragmentation.

The present disclosure provides a solar cell backsheet. The integrated functional layer can replace the adhesive film between the cell sheet and the backsheet in the traditional module, and still provide high weatherability, high reflection, high insulation, and low water permeability to protect the module for 25-year of service life and increase the module power.

The disclosure discloses a solar cell backsheet, which has a functional layer that can replace the existing adhesive film layer that is in contact with the cell sheet, is integrated with the backsheet, and the functional layer adopts the transparent layer and the milky layer structure, of which the milky layer is a functional enhancement layer. Through the multilayer structure design and optimization of different layer thicknesses and formulas, the peel strength of the backsheet itself can be enhanced. At the same time, the use of its internal formula and composition ratio causes the backsheet to have good temperature resistance, meets the requirements of high system voltage, and has high reflection and low water permeability. The transparent layer is bonded to the cell, and the microporous structure on the surface can strengthen the bonding strength with the cell to greater than 40 N/cm. At the same time, through the multilayer structure design and formulation adjustment, the phase interface between the transparent layer and the milky layer is diluted, and the compatibility between the two is improved. The most important thing is that the transparent layer and the milky layer in the functional layer can be a multi-layer structure integrally extruded and obtained. It can effectively protect the cell sheet from cracking and fragmenting during the lamination process, making it reliable while improving a series of functionalities such as insulation, blocking, temperature resistance, and high reflection.

In the present disclosure, the solar cell backsheet disclosed by the present disclosure has the following features:

1. The integrated functional layer has a multi-layer structure. The transparent layer can effectively ensure the adhesion to the cell sheet and the underlying film. At the same time, the transparent layer is made of polyolefin elastomer and plastomer, which can effectively protect the cell sheet from cracking and fragmenting;

2. The white structure in the integrated functional layer uses modified resin, which has good temperature resistance. The conductor will not completely penetrate the substitute layer and cause it to lose its insulation effect. It is qualified for working environments with higher system voltage, greatly reducing the construction cost of the power station;

3. The emergence of an integrated functional layer reduces a step of a stacking process in the production of components. Today, the batch production of components can simplify the process and reduce the labor intensity of workers.

An embodiment of the present disclosure has been described in detail above, but the contents are only a preferred embodiment of the present disclosure and should not be considered as limiting the scope of implementation of the disclosure. All equal changes and improvements made in accordance with the scope of the present disclosure's application are covered by the scope of the disclosure's patent.

What is claimed is:

1. A solar cell backsheet comprising:
a weathering layer;
a first adhesive layer;
a polyethylene terephthalate (PET) layer;
a second adhesive layer; and
a functional layer; wherein:
the weathering layer, the first adhesive layer, the PET layer, the second adhesive layer, and the functional layer are arranged in said sequence; and
the functional layer comprises a milky layer and a transparent layer, the milky layer and the transparent layer being integrally formed.

2. The solar cell backsheet of claim 1, wherein:
the milky layer comprises at least one layer, a thickness of the milky layer being in a range of 20-200 μm; and
the transparent layer comprises at least one layer, a thickness of the transparent layer being in a range of 200-800 μm.

3. The solar cell backsheet of claim 2, wherein:
the milky layer comprises at least 3 parts of modified inorganic filler, at least 70 parts of modified resin, at least 0.3 parts of ultraviolet absorbent, and at least 0.3 parts of antioxidant; and
the transparent layer comprises at least 90 parts of modified resin, at least 0.3 parts of ultraviolet absorber, and at least 0.3 parts of antioxidant.

4. The solar cell backsheet according to claim 3, wherein:
the milky layer comprises a plurality of layers, the content of the modified resin in the layer of the milky layer bonded to the transparent layer is not higher than the content of the modified resin in the layer of the milky layer bonded to the adhesive layer, and the thickness of the layer of the milky layer bonded to the transparent layer is not higher than the thickness of the layer of the milky layer bonded to the adhesive layer.

5. The solar cell backsheet according to claim 4, wherein:
the transparent layer comprises a plurality of layers, the content of the modified resin in the layer of the transparent layer bonded to the cell sheet is not less than the content of the modified resin in the layer of the transparent layer bonded to the milky layer, and the thickness of the layer of the transparent layer bonded to the cell sheet is not higher than the thickness of the layer of the transparent layer bonded to the milky layer.

6. The solar cell backsheet according to claim 5, wherein:
a thickness of the weathering layer is in a range of 5-200 μm and the weathering layer is a fluorine-containing or non-fluorine-containing layer.

7. The solar cell backsheet according to claim 6, wherein the adhesive layer is an acrylic adhesive, a polyurethane adhesive, an epoxy resin adhesive, or a resin adhesive, a thickness of the adhesive layer is in a range of 5-30 μm.

8. The solar cell backsheet according to claim 7, wherein the modified resin comprises one or a combination of polyethylene, polypropylene, ethylene copolymer, polyolefin elastomer, and polyolefin plastomer.

9. The solar cell backsheet according to claim 8, wherein the modified inorganic filler is one or a combination of titanium dioxide, montmorillonite, kaolin, mica, talc, wollastonite, and brucite.

10. The solar cell backsheet according to claim 9, wherein both major surfaces of the functional layer comprise microstructures by embossing.

11. A solar cell backsheet comprising:
a weathering layer;
a first adhesive layer;
a polyethylene terephthalate (PET) layer;
a second adhesive layer; and
a functional layer; wherein:
the weathering layer, the first adhesive layer, the PET layer, the second adhesive layer, and the functional layer are arranged in said sequence;
the functional layer comprises a milky layer and a transparent layer, the milky layer and the transparent layer being integrally formed;
the milky layer comprises at least one layer, a thickness of the milky layer being in a range of 20-200 μm; and
the transparent layer comprises at least one layer, a thickness of the transparent layer being in a range of 200-800 μm.

12. The solar cell backsheet of claim 11, wherein:
the milky layer comprises at least 3 parts of modified inorganic filler, at least 70 parts of modified resin, at least 0.3 parts of ultraviolet absorbent, and at least 0.3 parts of antioxidant; and
the transparent layer comprises at least 90 parts of modified resin, at least 0.3 parts of ultraviolet absorber, and at least 0.3 parts of antioxidant.

13. The solar cell backsheet of claim 12, wherein:
the weathering layer is a polyvinylidene fluoride (PVDF) film with a thickness of 35 μm;
each of the first adhesive layer and the second adhesive layer is a polyurethane adhesive with a thickness of 10 μm;
a thickness of the PET layer is 200 μm; and
the functional layer comprises a single-layer milky layer and a single-layer transparent layer.

14. The solar cell backsheet of claim 13, wherein:
the milky layer has a thickness of 90 μm and comprises 25 parts of polyethylene, 45 parts of polyolefin elastomer, 19 parts of polyolefin plastomer, 10 parts of titanium dioxide, 0.4 parts of antioxidant, and 0.6 parts of UV absorber; and
the transparent layer has a thickness of 400 μm and comprises 60 parts of polyolefin elastomer, 39 parts of ethylene-vinyl acetate copolymer, 0.4 parts of antioxidant, and 0.4 parts of ultraviolet absorber.

15. The solar cell backsheet of claim 12, wherein:
the weathering layer is a weather-resistant PET having a thickness of 35 μm;
each of the first adhesive layer and the second adhesive layer is an acrylic adhesive having a thickness of 10 μm;
a thickness of the PET layer is 200 μm; and
the functional layer comprises a double-layer milky layer and a single-layer transparent layer.

16. The solar cell backsheet of claim 15, wherein:
a thickness of the layer of the milky layer bonded to the transparent layer is 20 μm and comprises 29 parts of polyethylene, 55 parts of polyolefin elastomer, 5 parts of polyolefin plastomer, 10 parts of titanium dioxide, 0.4 parts of antioxidant, and 0.6 parts of ultraviolet absorber;
a thickness of the layer of the milky layer not bonded to the transparent layer has a thickness of 90 μm and comprises 25 parts of polyethylene, 45 parts of polyolefin elastomer, 19 parts of polyolefin plastomer, 10 parts of titanium dioxide, 0.4 parts of antioxidant, and 0.6 parts of ultraviolet absorber; and
the transparent layer has a thickness of 400 μm and comprises 60 parts of olefin elastomer, 39 parts of ethylene-vinyl acetate copolymer, 0.4 parts of antioxidant, and 0.6 parts of ultraviolet absorber.

17. The solar cell backsheet of claim 12, wherein:
the weathering layer is a PVDF film with a thickness of 35 μm;
each of the first adhesive layer and the second adhesive layer is a polyurethane adhesive with a thickness of 10 μm;
a thickness of the PET layer is 200 μm; and
the functional layer comprises a single-layer milky layer and a double-layer transparent layer.

18. The solar cell backsheet of claim 17, wherein:
the milky layer has a thickness of 100 μm and comprises 25 parts of polyethylene, 45 parts of polyolefin elastomer, 19 parts of polyolefin plastomer, 10 parts of titanium dioxide, 0.4 parts of antioxidant, and 0.6 parts of ultraviolet absorber;
the layer of the transparent layer bonded to the milky layer has a thickness of 400 μm and comprises 60 parts of polyolefin elastomer, 39 parts of ethylene-vinyl acetate copolymer, 0.4 parts of antioxidant, and 0.6 parts of ultraviolet absorber; and
the layer of the transparent layer not bonded to the milky layer has a thickness of 20 μm and comprises 40 parts of polyolefin elastomer, 59 parts of ethylene-vinyl acetate copolymer, 0.4 parts of antioxidant, and 0.6 parts of UV absorber.

19. The solar cell backsheet of claim 12, wherein:
the weathering layer is a fluorine-containing film with a thickness of 35 μm;
each of the first adhesive layer and the second adhesive layer is a polyurethane adhesive with a thickness of 10 μm;
the PET layer has a thickness of 200 μm; and
the functional layer comprises a double-layer milky layer and a double-layer transparent layer.

20. The solar cell backsheet of claim 19, wherein:
the layer of the milky layer bonded to the PET layer has a thickness of 90 μm and comprises 25 parts of polyethylene, 45 parts of polyolefin elastomer, 19 parts of polyolefin plastomer, 10 parts of titanium dioxide, 0.4 parts of antioxidant, and 0.6 parts of ultraviolet absorber;
the layer of the milky layer bonded to the transparent layer has a thickness of 30 μm and comprises 29 parts of polyethylene, 55 parts of polyolefin elastomer, 5 parts of polyolefin plastomer, 10 parts of titanium dioxide, 0.4 parts of antioxidant, and 0.6 parts of ultraviolet absorber;
the layer of the transparent layer bonded to the milky layer has a thickness of 400 μm and comprises 60 parts of polyolefin elastomer, 39 parts of ethylene-vinyl acetate copolymer, 0.4 parts of antioxidant, and 0.6 parts of ultraviolet absorber; and
the layer of the transparent layer not bonded to the milky layer has a thickness of 50 μm and comprises 40 parts of polyolefin elastomer, 59 parts of ethylene-vinyl acetate copolymer, 0.4 parts of antioxidant, and 0.6 parts of ultraviolet absorber.
